(19) United States
(12) Patent Application Publication
(10) Pub. No.: US 2014/0022682 A1
(43) Pub. Date: Jan. 23, 2014

(54) PACKAGED CHIP INTEGRATED WITH A SIGNAL ISOLATION TRANSFORMER AND A PROTECTIVE COMPONENT

(71) Applicant: Wendell Industrial Co., Ltd., New Taipei City (TW)

(72) Inventor: Chun-Hong LEE, New Taipei City (TW)

(21) Appl. No.: 13/943,267

(22) Filed: Jul. 16, 2013

(30) Foreign Application Priority Data
Jul. 23, 2012 (TW) 101214193

(51) Int. Cl. H01L 27/02

(52) U.S. Cl. CPC H01L 27/0248
USPC 361/91.1

(57) ABSTRACT

The present invention is to provide a packaged chip having a protective component integrated with a signal isolation transformer, wherein the signal isolation transformer comprises a primary side and a secondary side, and the primary side includes an input port electrically connected to the signal input slot, and a primary side central tapped port, and the secondary side includes an output port electrically connected to the internal signal processing unit and a secondary side central tapped port. Using such structure, the chip has the functions of surge protection as well as noise treatment, and the problem that the conventional protective circuit occupying too much space is solved.

### BACKGROUND OF THE INVENTION

1. Field of the Invention

The invention relates to a structure of a packaged chip, and more particularly to a packaged chip integrated with signal isolation transformers and protective components.

2. Description of Related Art

Along with the development of electronic technology, advanced computers with high calculating ability are now commonly used by the general public. Moreover, as a result of the popularization of the Internet, users all over the world have become closer and closer to each other, and the amount as well as the variety of information circulating on the Internet is so massive that we can even call this age an age of “information explosion.” Currently, in spite of wireless networks like 4G and Wi-Fi, the mainstream technology of Internet access is still the more reliable and more stable wired networks with physical electric cables by means of which different computers transmit data to one another. However, for the sake of convenience, the electric cables mentioned above are often installed nakedly around the exterior of a building. Consequently, if the electric cables are struck by a lightning, the high-voltage electric current thus generated will immediately transmit to modems and computers connected with the cables and destroy the modems and computers with the high voltage.

To avoid this problem, Taiwan Patent No. M396531 discloses an improved structure of connector with protective components. The structure of connector comprises an insulating main body, a signal transmitting module installed inside the insulating main body, and a first protective component set and a second protective component set, wherein the first protective component set and the second protective component set are electrically connected to the signal transmitting module. The signal transmitting module comprises a circuit board with emplaced circuits, and an input terminal set and an output terminal set that are electrically connected to the circuit board. The first protective component set is electrically connected between the input terminal set and the output terminal set, providing protection for the electrical connection between circuits. The second protective component set is electrically connected between the first protective component set and the ground wire, providing protection for the electrical connection between circuits and ground wires. However, the first protective component set of the above-mentioned connector is installed at the secondary side (low-voltage side). If high-voltage surges enter, because coils of the primary side cannot properly transmit the surges to the ground terminal through the protective component, the coils (that is, the primary side and the secondary side) will be destroyed by high temperature generated by the high power currents.

### SUMMARY OF THE INVENTION

The purpose of the invention is to provide a packaged chip having a protective component integrated with a signal isolation transformer so that the chip has the functions of surge protection as well as noise treatment, and the problem that the conventional protective circuit occupying too much space is solved. In addition, the problem that the overvoltage protection component installed in the secondary side so that the primary side cannot be effectively protected is also solved by the present invention.

In order to achieve the above mentioned purpose, one aspect of the present invention is to provide a packaged chip integrated with a signal isolation transformer and a protective component, wherein the packaged chip is installed on a network switch which includes a signal input slot and an internal signal processing unit, and the packaged chip comprises: a package part, which comprises an accommodation space and at least two signal isolation transformers installed inside the accommodation space, wherein the signal isolation transformer comprises a primary side and a secondary side, wherein the primary side includes an input port electrically connected to the signal input slot, and a primary side central tapped port, and the secondary side includes an output port electrically connected to the internal signal processing unit and a secondary side central tapped port; and a substrate, which is assembled and installed on an open side of the accommodation space, wherein the substrate includes a bearing surface which is installed corresponding to the signal isolation transformer, wherein comprises at least one first overvoltage protection component which is connected in parallel to the output port and which changes from high impedance into low impedance when the voltage of the output port is higher than the value of the first voltage constant, and/or at least one second overvoltage protection component which is connected in series to the primary side central tapped port and which changes from high impedance into low impedance when the voltage of the primary side central tapped port is higher than the value of the second voltage constant, and a ground wire installed on the substrate for one end of the second overvoltage protection component to electrically connect.

In a preferable embodiment, the packaged chip integrated further comprises a bridge rectifier electrically connected to two primary side central tapped ports to capture direct currents of the input port for the network switch to use.

In a preferable embodiment, the primary side and the secondary side are paired with each other and are installed at two sides of the accommodation space, and the ground wire includes a first guiding line that extends toward both ends of the bearing surface and at least one second guiding line which is electrically connected to the first guiding line and which extends toward the primary side on the substrate.

In a preferable embodiment, the package part includes at least two ground pins electrically connected to the ground wire respectively.

In a preferable embodiment, the package part includes a plurality of connecting pins that are electrically connected respectively to the input port, the output port, the primary side central tapped port, and the secondary side central tapped port.

In a preferable embodiment, the package part includes a plurality of electrical contact points that are extended from the connecting pins respectively and are electrically connected to the connecting pins, and the substrate includes a plurality of electrical connection parts for the electrical contact points to insert for further electric welding.

In a preferable embodiment, the first overvoltage protection component is a transient voltage suppressor.

In a preferable embodiment, the second overvoltage protection component is a gas discharge tube.

Another aspect of the invention is to provide a packaged chip integrated with a signal isolation transformer and a protective component, wherein the packaged chip is installed on a network switch which includes a signal input slot and an internal signal processing unit, and the packaged chip comprises: a package part, which comprises an accommodation space and at least two signal isolation transformers installed inside the accommodation space, wherein the signal isolation transformer comprises a primary side and a secondary side, wherein the primary side includes an input port electrically connected to the signal input slot, and a primary side central tapped port, and the secondary side includes an output port electrically connected to the internal signal processing unit and a secondary side central tapped port; and a substrate, which is assembled and installed in the accommodation space of the package part, wherein the substrate includes a bearing surface which is installed corresponding to one side of the signal isolation transformer, wherein comprises at least one first overvoltage protection component which is connected in parallel to the output port and which changes from high impedance into low impedance when the voltage of the output port is higher than the value of the first voltage constant, and/or at least one second overvoltage protection component which is connected in series to the primary side central tapped port and which changes from high impedance into low impedance when the voltage of the primary side central tapped port is higher than the value of the second voltage constant, and a ground wire installed on the substrate for one end of the second overvoltage protection component to electrically connect.

In a preferable embodiment, the package part includes a lower package component and an upper package component assembled and installed above the lower package component, wherein the substrate is installed in between the upper package component and the lower package component, dividing the accommodation space into a first installation area and a second installation area, wherein the first installation area is for the installation of the signal isolation transformer and the second installation area is for the installation of the first overvoltage protective component and the second overvoltage protective component.

In a preferable embodiment, the lower package component includes a plurality of connecting pins that are electrically connected respectively to the input port, the output port, the primary side central tapped port, and the secondary side central tapped port.

In a preferable embodiment, the lower package component includes a plurality of electrical contact points that are extended from the connecting pins and electrically connected to the connecting pins, and the substrate includes a plurality of electrical connection parts for the electrical contact points to insert for further electric welding.

In a preferable embodiment, the packaged chip integrated with the signal isolation transformer further connects a bridge rectifier electrically connected to two primary side central tapped ports to capture direct currents of the input port for the network switch to use.

In a preferable embodiment, the primary side and the secondary side are paired with each other and are installed at two sides of the accommodation space, and the ground wire includes a first guiding line that extends toward both ends of the substrate and at least one second guiding line which is electrically connected to the first guiding line and which extends toward the primary side on the substrate.

In a preferable embodiment, the package part includes at least two ground pins electrically connected to the ground wire respectively.

In a preferable embodiment, the first overvoltage protection component is a transient voltage suppressor.

In a preferable embodiment, the second overvoltage protection component is a gas discharge tube.

Therefore, the present invention is to integrate a signal isolation transformer and an overvoltage protection component onto a single chip to minimize the volume of the product. In addition, because of the protective component and the signal isolation transformer is integrated in a modulation manner, the gas discharge tube and the transient voltage suppressor can be installed in the primary side (high-voltage side) and the secondary side (low-voltage side) respectively to prevent the primary side and the secondary side from damage. Furthermore, because of the ground wire installed on the substrate, the chip of the present invention has the connection pins for the circuit assembling person to use without the inconvenience of finding extra usable ground line.

### BRIEF DESCRIPTION OF THE DRAWINGS

FIG. 1 is the schematic diagram of usage state of the first embodiment of the invention.

FIG. 2 and FIG. 3 are the decomposition schematic diagrams of partial structure of the first embodiment of the invention.

FIG. 4 is the schematic diagram of circuits of the first embodiment of the invention.

FIG. 5 is the decomposition schematic diagram of structure of the second embodiment of the invention.

FIG. 6 is the sectional schematic diagram of the second embodiment of the invention.

### DETAILED DESCRIPTION OF THE INVENTION

The detailed description and the technical content of the invention will now be expounded with the help of illustrations:

The use of the word “a” or “an” when used in conjunction with the term “comprising” in the claims and/or the specification may mean “one,” but is also consistent with the meaning of “one or more,” “at least one,” and “one or more than one.”

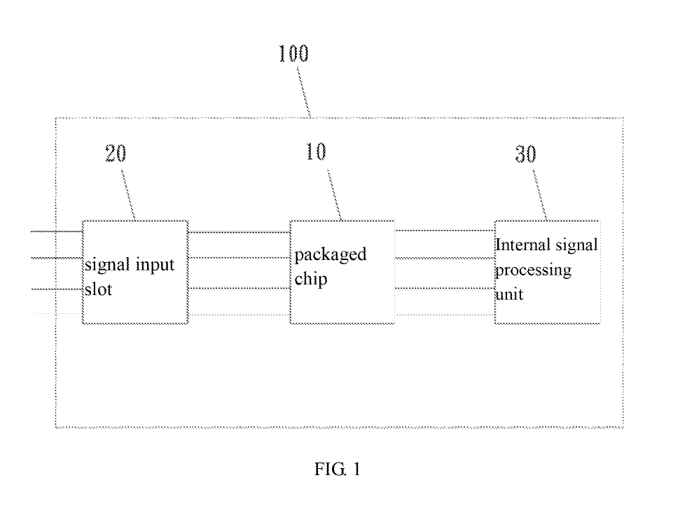

Please refer to FIG. 1, the schematic diagram of usage state of the first embodiment of the present invention. As the diagram shows, the invention is a packaged chip (10) integrated with a signal isolation transformer and a protective component, and the packaged chip (10) is installed on a network switch (100). The network switch (100) at least includes a signal input slot (20) and an internal signal processing unit (30), wherein the signal input slot (20) is in coordination with the mainstream signal cable RJ-45. The packaged chip (10) of the invention is installed at the back end of the signal input slot (20), so as to transmit or receive digital signals through the signal input slot (20), wherein the interferences can be removed and the possibility of surges destroying internal coils can be reduced. Moreover, after interferences are removed, the signals are transmitted to the internal signal processing unit (30) for it to further analyze the data.

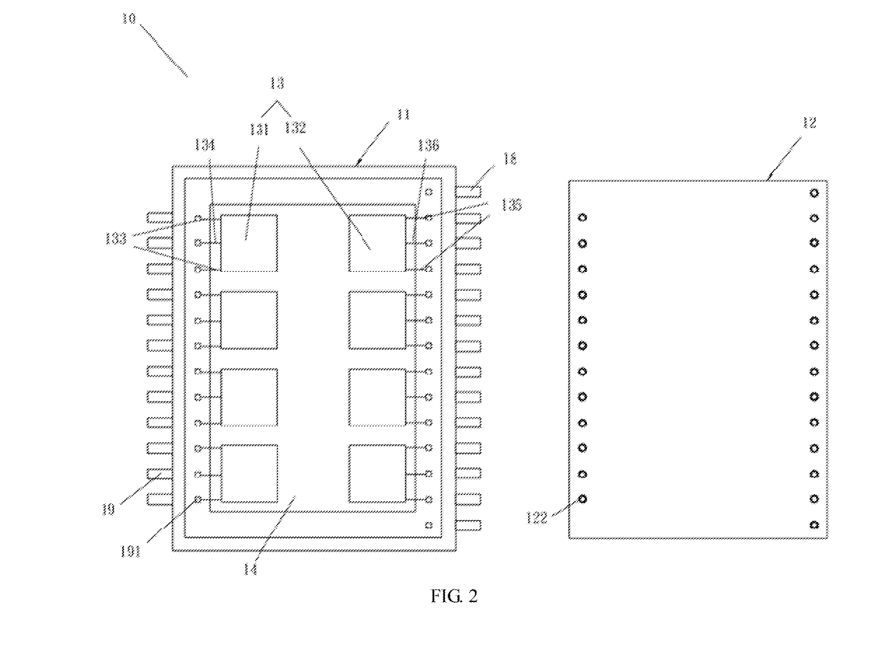

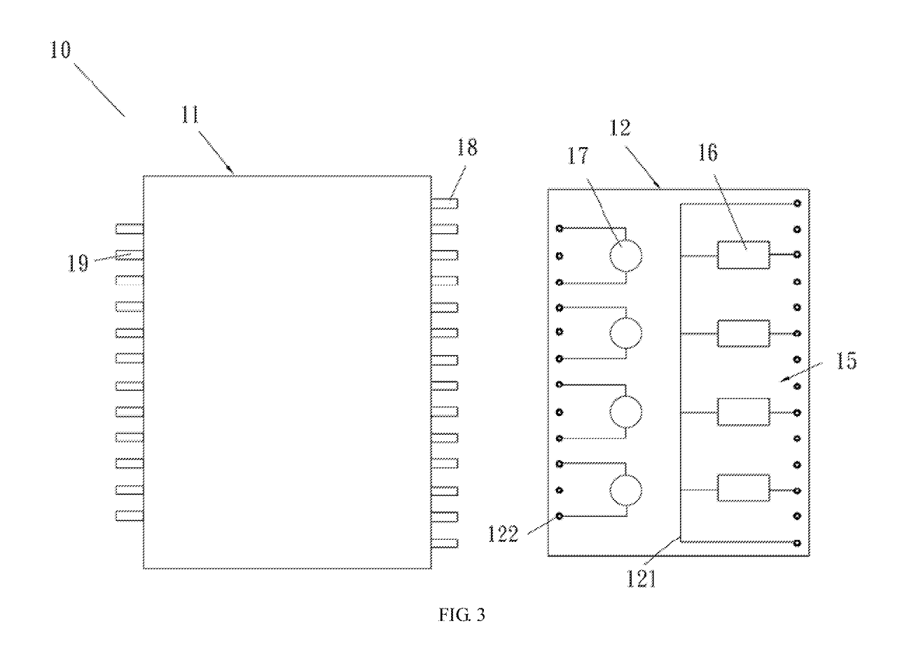

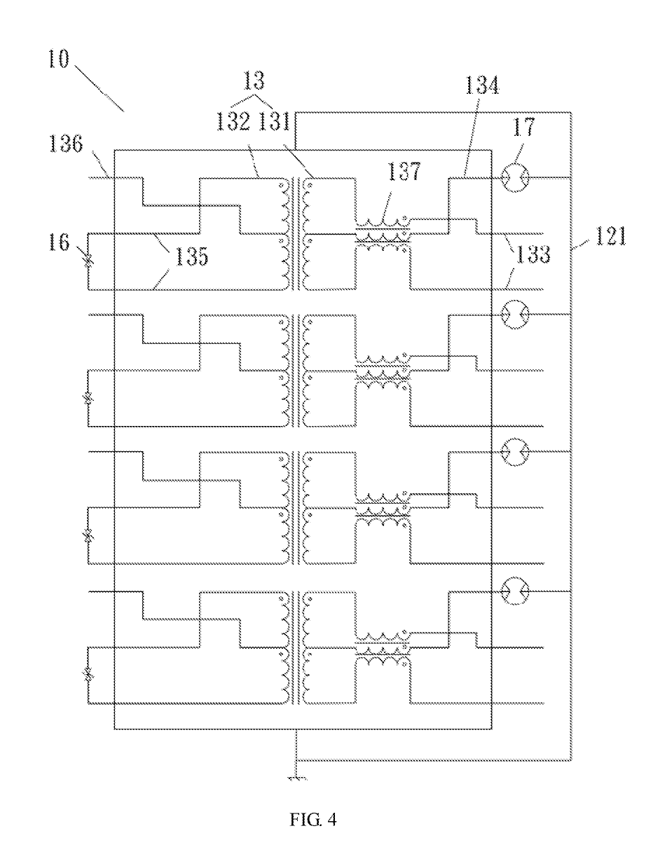

Regarding the complete structure and the package technique of the first embodiment of the packaged chip of the invention, please refer to FIG. 2 together with FIG. 3, the breakdown schematic diagrams of partial structure of the packaged chip of the present invention. As the diagrams show, the packaged chip (10) of the invention includes a package part (11) and a substrate (12) installed on one side of the package part (11) for bearing internal components. The package part (11) includes an accommodation space (14), wherein four signal isolation transformers (13) are installed in the accommodation space (14) by glue adhesion on the package part (11). The number of the signal isolation transformers (13) installed can vary according to different Ethernet standards. For example, the Ethernet standard 100Based-T only requires the installation of two signal isolation transformers (13). The present embodiment is designed for the Ethernet standards 1000Based-T and 10G Based-T, and is backward compatible with Ethernet standards 10/100Based-T. However, the compatibility with these Ethernet standards is only a particular trait of one specific embodiment of many possible embodiments of the invention, and therefore does not limit the desired technical claim of the invention. Take the signal isolation transformers (13) of the Ethernet standard 1000Based-T for example, the four signal isolation transformers (13) can coordinate with two signal transceivers, wherein each signal transceiver includes a data transmitting line and a data receiving line, in which each data transmitting line and data receiving line respectively coordinate with an signal isolation transformer (13). Take the data receiving line for example, each signal isolation transformer (13) includes a primary side (131) and a secondary side (132) that is coupled to the primary side (131). The primary side (131) includes an input port (133) that is electrically connected with the signal input slot (20), and a primary side central tapped port (134) that captures the direct current signals of the input port (133). The secondary side (132) includes an output port (135) which receives signals removed of interferences from the input port (133) and which transmits signals from the input port (133) to the signal processing unit, and a secondary side central tapped port (136) (it should be noticed that the secondary side central tapped port could be optionally added by the person having ordinary skill in the art, and it can be understood that the implementation without the object should be equivalent to the scope of the invention). To remove interferences from signals, in the present embodiment, the primary side (131) includes two corresponding interference-neutralizing coils (137) that are respectively connected in series to the input port (133) and the primary side central tapped port (134) as shown in FIG. 4 for the removal of common-mode interferences. The two interference-neutralizing coils (137) can also be installed at the secondary side (132) and are respectively connected in series to the output port (135) and the secondary side central tapped port (136).

The substrate (12) is installed at the open side of the accommodation space (14) above the package part (11), including a bearing surface (15) installed at the direction corresponding to the accommodation space (14). For the convenience of the integration of the packaged chip (10) of the invention and the circuit board (not shown), the package part (11) includes twenty-four connecting pins (19) that are electrically connected respectively to the input port (133), the output port (135), the primary side central tapped port (134), and the secondary side central tapped port (136). Moreover, a plurality of electrical contact points (191) that are extended from the connecting pins (19) and are electrically connected to the connecting pins (19) are installed at the location corresponding to the open side of the accommodation space (14) on the substrate (12), in correspondence with a plurality of electrical connection parts (122) installed on the substrate (12), so that the electrical contact points (191) are able to be inserted on the electrical connection parts (122) for the tight combination of the substrate (12) and the package part (11).

On the substrate (12), there are at least one first overvoltage protection component (16) that is connected in parallel to the output port (135) through the electrical connection part (122) and the electrical contact point (191), and at least one second overvoltage protection component (17) that is connected in series to the primary side central tapped port (134) through the electrical connection part (122) and the electrical contact point (191). Because the first overvoltage protection component (16) is installed at the secondary side (132), it can be a transient voltage suppressor (TVS), which is faster in reaction, in order to protect the internal components of the network switch (100). On the other hand, because the second overvoltage protection component (17) is installed at the primary side (131), it can be a gas discharge tube (GDT), which is more tolerant to high-voltage surges. The first overvoltage protection component (16) and the second overvoltage protection component (17) have similar characteristic as that of Zener diode, which causes avalanche currents when the voltage is higher than a certain value. When a surge voltage enters, the gas discharge tube and the transient voltage suppressor can detect the surge voltage immediately, and characteristically changes their high impedance into low impedance, forming short circuits for the release of energy.

To avoid the trouble that circuit assembling person have to install additional ground wires (121) when installing the packaged chip (10) of the present invention, and to prevent the problem that future installation of ground wires on the circuit board would occupy too much space of the circuit board, in the present invention, there is a ground wire (121) installed on the bearing surface (15) of the substrate (12). The primary side (131) and the secondary side (132) are paired with each other and are installed at the two sides of the accommodation space (14). The ground wire (121) includes a first guiding line (123) that extends along both directions of the bearing surface (15), and at least one second guiding line (124) that is electrically connected to the first guiding line (123) and extends toward the direction of the primary side (131) on the substrate, so as to divide the primary side (high-voltage side) (131) and the secondary side (low-voltage side) (132). The two second guiding lines (124) are electrically connected to two ground pins (18) installed on the package part (11) close to the direction of the primary side (131) respectively. The ground wire (121) is also available for electrical connection to one end of the second overvoltage protection component (17). Therefore, the circuit assembling person can electrically connect the ground wire (121) to an external case (not shown) through the ground pins (18). When surge voltage enters through the signal input slot (20), the second overvoltage protection component (17) will form a short circuit state, wherein the energy will be able to come to the ground wire (121) through the guidance of the second overvoltage protection component (17), and be released in the external case (not shown) through the guidance of the ground wire (121). It is important to mention that the extending direction of the ground wire (121) is only a preferred embodiment of the invention, and therefore does not limit the range of claim of the invention. In other words, it has to be clarified that the position of installation of pins can change according to the need of each manufacturing process, and is not intended to limit the claim of the invention.

In order to match the installation of the network standard Power over Ethernet (POE), the packaged chip (10) of the present invention includes two power output ports (135) on the substrate (12) that are respectively and connected in parallel to as well as installed in between the two primary side central tapped ports (134) and the protective component of the second overvoltage protection component (17). The network switch (100) includes a bridge rectifier capable of supplying power to all internal units, capturing direct current signals of the two input port (133) through the primary side central tapped port (134) and removing signal interferences as well as adequately arranging positive and negative ends by the bridge rectifier for the arrangement of internal units of the network switch (100).

Regarding the operation mode of the circuits of the invention, please refer to FIG. 4, the schematic diagram of circuits of the present invention. As the diagram shows, when a lightning surge strikes the external cable (not shown), transmits its voltage to the signal input signal (20), and causes the voltage of the primary side central tapped port (134) higher than the value of the second voltage constant, the gas discharge tube (the second overvoltage protection components (17)) connected in parallel to the primary side (131) produces a breakdown electric arc because of the high voltage of the surge, making the impedance of the gas discharge tube much lower than the impedance of the primary side (131), wherein most of the surge energy will be guided to the ground wire (121) by the gas discharge tube and outwardly release. At the same time, to avoid the possibility that the gas discharge tube is unable to release timely the high-voltage surges brought in by the lightning strike and cause the circuits at the back end of the secondary side (132) to be destroyed, when the voltage of the output port (135) of the secondary side (132) is higher than the value of the first voltage constant, the transient voltage suppressor (the first overvoltage protection component (16)) connected in parallel to the output port (135) will form a reverse breakdown current because of the breakthrough of the high-voltage surge, wherein the impedance of the transient voltage suppressor is much lower than the impedance of the internal circuits of the network switch (100), making the transient voltage suppressor and the secondary side (132) form a closed loop and therefore preventing the surge of the lightning strike from entering into the internal circuits of the network switch (100). The values of the first voltage constant and the second voltage constant are set according to the safety standard of the industry, and therefore do not limit the claim of the invention.

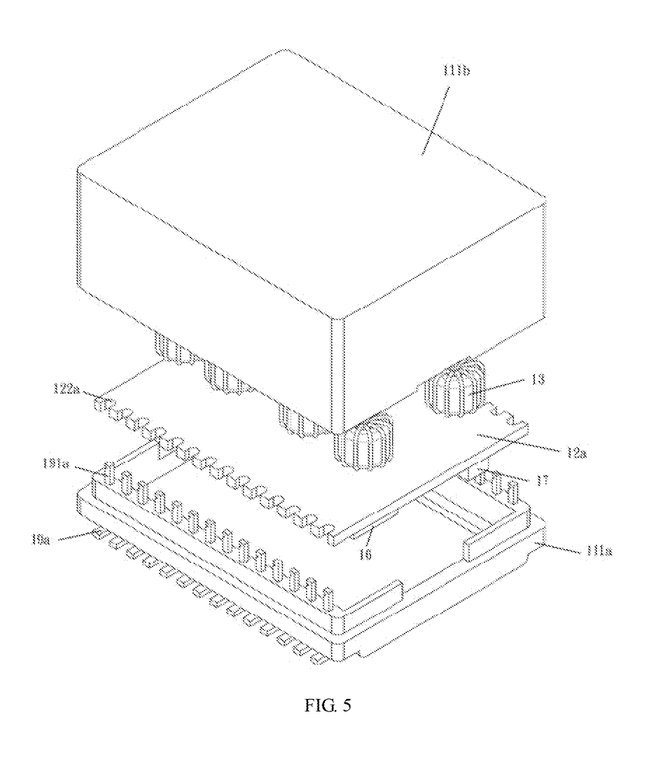

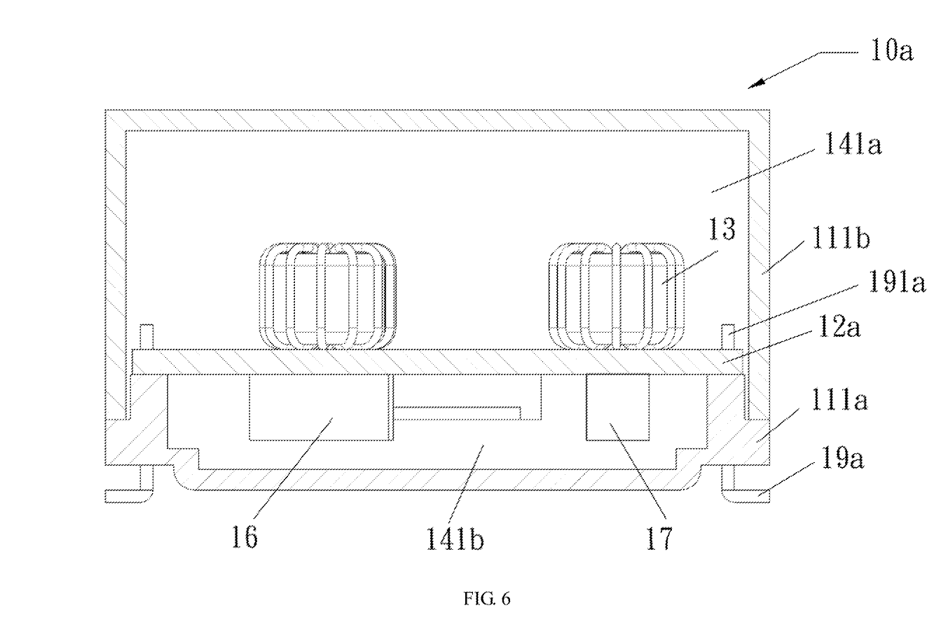

Please refer to FIG. 5 and FIG. 6 of the invention, the decomposition schematic diagrams of structure of the second embodiment of the present invention. As the diagrams show, the differences of the embodiment from the first embodiment lies in the location of installation of the substrate (12) and the direction of installation of the bearing surface (15). To differentiate the signal isolation transformers (13), the first overvoltage protection component (16), and the second overvoltage protection component (17), the package part (11) can be divided into a lower package component (111a) and an upper package component (111b) installed above the lower package component (111a). The substrate (12) is installed inside the accommodation space of the package part, and the bearing surface (15) is installed opposite to the signal isolation transformers (13), so as to divide the accommodation space into a first installation area (141a) and a second installation area (141b). The first installation area is for the installation of the signal isolation transformers (13), and the second installation area is for the installation of the first overvoltage protection component (16) and the second overvoltage protection component (17). In addition, because the circuits are etched at the side corresponding to the first overvoltage protection component (16) and the second overvoltage protection component (17) on the substrate (12a), the signal isolation transformers (13) can be prevented from contacting with the first overvoltage protection component (16) and the second overvoltage protection component (17) or their lines, thus stabilizing signals, decreasing electromagnetic interferences, and improving the safety of the circuits. A plurality of connecting pins (19a) are installed on the lower package component (111a), and there are a plurality of electrical contact points (191a) extended from the plurality of connecting pins (19a) for the insertion of electrical connection part (122a) on the substrate (12) to form an electrical connection.

To summarize, the invention can reduce the space the product occupies by the integration of the signal isolation transformers and the overvoltage protection components on a single chip, and makes the gas discharge tube and the transient voltage suppressor able to be installed respectively on the primary side (high-voltage side) and the secondary side (low-voltage side) by integrating the protective components to the signal isolation transformers through modularization, preventing the primary side and the secondary side from destruction. In addition, through the ground wire installed on the substrate, the single chip of the invention possesses ground pins for circuit assembling person to utilize, without the inconvenience of finding extra usable ground line.

While the invention has been described in terms of preferred embodiments, those skilled in the art will recognize that the invention can be practiced with modifications within the spirit and scope of the appended claims.

What is claimed is:

1. A packaged chip integrated with a signal isolation transformer and a protective component, wherein the packaged chip is installed on a network switch which includes a signal input slot and an internal signal processing unit, and the packaged chip comprises:
a package part, which comprises an accommodation space and at least two signal isolation transformers installed inside the accommodation space, wherein the signal isolation transformer comprises a primary side and a secondary side, wherein the primary side includes an input port electrically connected to the signal input slot, and a primary side central tapped port, and the secondary side includes an output port electrically connected to the internal signal processing unit and a secondary side central tapped port; and
a substrate, which is assembled and installed on an open side of the accommodation space, wherein the substrate includes a bearing surface which is installed corresponding to the signal isolation transformer, wherein the bearing surface comprises at least one first overvoltage protection component which is connected in parallel to the output port and which changes from high impedance into low impedance when the voltage of the output port is higher than the value of the first voltage constant, and/or at least one second overvoltage protection component which is connected in series to the primary side central tapped port and which changes from high impedance into low impedance when the voltage of the primary side central tapped port is higher than the value of the second voltage constant, and a ground wire installed on the substrate for one end of the second overvoltage protection component to electrically connect.

2. The packaged chip integrated with the signal isolation transformer and the protective component of claim 1, which further comprises a bridge rectifier electrically connected to two primary side central tapped ports to capture direct currents of the input port for the network switch to use.

3. The packaged chip integrated with the signal isolation transformer and the protective component of claim 1, wherein the primary side and the secondary side are paired with each other and are installed at two sides of the accommodation space, and the ground wire includes a first guiding line that extends toward both ends of the bearing surface and at least one second guiding line which is electrically connected to the first guiding line and which extends toward the primary side on the substrate.

4. The packaged chip integrated with the signal isolation transformer and the protective component of claim 1, wherein the package part includes at least two ground pins electrically connected to the ground wire respectively.

5. The packaged chip integrated with the signal isolation transformer and the protective component of claim 1, wherein the package part includes a plurality of connecting pins that are electrically connected respectively to the input port, the output port, the primary side central tapped port, and the secondary side central tapped port.

6. The packaged chip integrated with the signal isolation transformer and the protective component of claim 5, wherein the package part includes a plurality of electrical contact points that are extended from the connecting pins respectively and are electrically connected to the connecting pins, and the substrate includes a plurality of electrical connection parts for the electrical contact points to insert for further electric welding.

7. The packaged chip integrated with the signal isolation transformer and the protective component of claim 1, wherein the first overvoltage protection component is a transient voltage suppressor.

8. The packaged chip integrated with the signal isolation transformer and the protective component of claim 1, wherein the second overvoltage protection component is a gas discharge tube.

9. A packaged chip integrated with a signal isolation transformer and a protective component, wherein the packaged chip is installed on a network switch which includes a signal input slot and an internal signal processing unit, and the packaged chip comprises:
a package part, which comprises an accommodation space and at least two signal isolation transformers installed inside the accommodation space, wherein the signal isolation transformer comprises a primary side and a secondary side, wherein the primary side includes an input port electrically connected to the signal input slot, and a primary side central tapped port, and the secondary side includes an output port electrically connected to the internal signal processing unit and a secondary side central tapped port; and
a substrate, which is assembled and installed in the accommodation space of the package part, wherein the substrate includes a bearing surface which is installed corresponding to one side of the signal isolation transformer, wherein the bearing surface comprises at least one first overvoltage protection component which is connected in parallel to the output port and which changes from high impedance into low impedance when the voltage of the output port is higher than the value of the first voltage constant, and/or at least one second overvoltage protection component which is connected in series to the primary side central tapped port and which changes from high impedance into low impedance when the voltage of the primary side central tapped port is higher than the value of the second voltage constant, and a ground wire installed on the substrate for one end of the second overvoltage protection component to electrically connect.

10. The packaged chip integrated with the signal isolation transformer and the protective component of claim 9, wherein the package part includes a lower package component and an upper package component assembled and installed above the lower package component, wherein the substrate is installed in between the upper package component and the lower package component, dividing the accommodation space into a first installation area and a second installation area, wherein the first installation area is for the installation of the signal isolation transformer and the second installation area is for the installation of the first overvoltage protective component and the second overvoltage protective component.

11. The packaged chip integrated with the signal isolation transformer and the protective component of claim 10, wherein the lower package component includes a plurality of connecting pins that are electrically connected respectively to the input port, the output port, the primary side central tapped port, and the secondary side central tapped port.

12. The packaged chip integrated with the signal isolation transformer and the protective component of claim 11, wherein the lower package component includes a plurality of electrical contact points that are extended from the connecting pins and electrically connected to the connecting pins, and the substrate includes a plurality of electrical connection parts for the electrical contact points to insert for further electric welding.

13. The packaged chip integrated with the signal isolation transformer and the protective component of claim 9, which further connects a bridge rectifier electrically connected to two primary side central tapped ports to capture direct currents of the input port for the network switch to use.

14. The packaged chip integrated with the signal isolation transformer and the protective component of claim 13, wherein the primary side and the secondary side are paired with each other and are installed at two sides of the accommodation space, and the ground wire includes a first guiding line that extends toward both ends of the substrate and at least one second guiding line which is electrically connected to the first guiding line and which extends toward the primary side on the substrate.

15. The packaged chip integrated with the signal isolation transformer and the protective component of claim 14, wherein the package part includes at least two ground pins electrically connected to the ground wire respectively.

16. The packaged chip integrated with the signal isolation transformer and the protective component of claim 9, wherein the first overvoltage protection component is a transient voltage suppressor.

17. The packaged chip integrated with the signal isolation transformer and the protective component of claim 9, wherein the second overvoltage protection component is a gas discharge tube.
